(19) United States
(12) Patent Application Publication
(10) Pub. No.: US 2009/0239334 A1
(43) Pub. Date: Sep. 24, 2009

(54) ELECTRODE FORMED IN APERTURE DEFINED BY A COPOLYMER MASK

(75) Inventors: Matthew J. Breitwisch, Yorktown Heights, NY (US); Matthew Colburn, Schenectady, NY (US); Eric Joseph, White Plains, NY (US); Chung Hon Lam, Peeksill, NY (US); Deborah A. Neumayer, Danbury, CT (US); Alejandro G. Schrott, New York, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 12/052,581

(22) Filed: Mar. 20, 2008

(51) Int. Cl. H01L 21/00

(52) U.S. Cl. 438/102; 257/E21.001

(57) ABSTRACT

A method of manufacturing a memory device is provided that in one embodiment includes providing an interlevel dielectric layer including a first via containing a memory material; forming at least one insulating layer on an upper surface of the memory material and the interlevel dielectric layer; forming an cavity through a portion of a thickness of the at least one insulating layer; forming a copolymer mask in at least the cavity, the copolymer mask including at least one opening that provides an exposed surface of a remaining portion of the at least one insulating layer that overlies the memory material; etching the exposed surface of the remaining portion of the at least one insulating layer to provide a second via to the memory material; and forming a conductive material within the second via in electrical contact with the memory material.

### FIELD OF THE INVENTION

In one embodiment, the present invention relates to electrode contacts to electrical devices. In another embodiment, the present invention relates to memory devices.

### BACKGROUND OF THE INVENTION

In semiconductor and memory device applications, an electrode is a conductor through which electric current is passed. An electrode is typically constructed of a metal, such as copper, tungsten, silver, lead, or zinc. An electrode may also be in the form of a nonmetallic conductor, including semiconducting materials, such as doped polysilicon.

Phase change memory (PCM) devices store data using a phase change material, such as, for example, a chalcogenide alloy, that transforms into a crystalline state or an amorphous state. An electrode may provide a current to the PCM device to produce heat that effectuates phase changes in the PCM between the crystalline and the amorphous phases. Each state of the phase change material has different resistance characteristics. Specifically, the phase change material in the crystalline state has low resistance and the phase change material in the amorphous state has high resistance. The crystalline state is typically referred to as a “set state” having a logic level “0”, and the amorphous state is typically referred to as a “reset state” having a logic level “1”.

### SUMMARY OF THE INVENTION

In one embodiment, the present invention utilizes a block copolymer to form nanoscale openings, e.g., nano-columnar openings, which may be filled with a conductive material to provide an electrode to a microelectronic device, such as a memory device. In one embodiment, the method includes:
providing an interlevel dielectric layer including a first via containing a memory material;
forming at least one insulating layer on an upper surface of the interlevel dielectric layer and on an upper surface of the memory material;
forming a cavity through a portion of a thickness of the at least one insulating layer, wherein a remaining portion of the at least one insulating layer overlies the memory material;
forming a copolymer mask in at least the cavity, the copolymer mask comprising at least one opening that provides an exposed surface of the remaining portion of the at least one insulating layer that overlies the memory material;
etching the exposed surface of the remaining portion of the at least one insulating layer to provide a second via to the memory material; and
forming a conductive material within the second via in electrical contact with the memory material.

In one embodiment, the step of forming the copolymer mask includes forming a copolymer layer on at least the remaining portion of the at least one insulating layer, segregating the copolymer into first units and second units, and removing at least one of the first units or second units with a selective developer. In one embodiment when the copolymer layer is composed of poly(styrene)-poly(methyl-methacrylate), the first units are poly(styrene), and the second units are poly(methyl-methacrylate). In one embodiment, when the copolymer layer is composed of poly(styrene)-poly(methyl-methacrylate), the copolymer layer comprises 70% polystyrene (PS) and 30% poly(methyl-methacrylate).

In one embodiment, the step of converting the copolymer layer into first units and the second units includes annealing at a temperature ranging from about 200° C. to about 300° C. for a time period ranging from about 1 hour to about 100 hours.

In one embodiment, the step of etching the exposed surface of the remaining portion of the at least one insulating layer to provide a second via to the memory material includes an anisotropic etch having an etch chemistry selective to the copolymer mask. In one embodiment, the at least one opening in the copolymer mask has sublithographic dimensions.

### BRIEF DESCRIPTION OF THE DRAWINGS

The following detailed description, given by way of example and not intended to limit the invention solely thereto, will best be appreciated in conjunction with the accompanying drawings, wherein like reference numerals denote like elements and parts, in which:

FIG. 1 is a side cross sectional view of an initial structure including a interlevel dielectric layer and conductive structures, e.g., interconnects, such as a metal stud, extending through the interlevel dielectric layer, as used in accordance with one embodiment of the present invention.

FIG. 2 is a side cross sectional view depicting recessing the upper surface of at least one conductive structure below the upper surface of the interlevel dielectric layer to provide at least one recessed conductive structure, in accordance with one embodiment of the present invention.

FIG. 3 is a side cross sectional view depicting forming a layer of a memory material atop the at least one recessed conductive structure, in accordance with one embodiment of the present invention.

FIG. 4 is a side cross sectional view depicting one embodiment of a planarization step, in accordance with the present invention.

FIG. 5 is a side cross sectional view depicting forming at least one insulating layer atop the upper surface of the memory material and the interlevel dielectric layer, and patterning the at least one insulating layer to provide a cavity overlying the memory material, in accordance with one embodiment of the present invention.

FIG. 6 is a side cross sectional view depicting a block mask that is formed in at least the cavity and is composed of a block copolymer, wherein the block copolymer is segregated and developed to provide a sublithographic opening overlying the memory material, in accordance with one embodiment of the present invention.

FIG. 7 depicts a side cross sectional view of an etch step utilizing the copolymer block mask to produce a via to the memory material, and depositing a conductive material within the via in electrical contact with the memory material, in accordance with one of embodiment of the present invention.

### DETAILED DESCRIPTION OF THE INVENTION

Detailed embodiments of the present invention are disclosed herein; however, it is to be understood that the disclosed embodiments are merely illustrative of the invention that may be embodied in various forms. In addition, each of the examples given in connection with the various embodiments of the invention are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the present invention.

The embodiments of the present invention relate to microelectronics, and in one embodiment to memory devices and electrodes to memory devices. When describing the inventive structures and methods, the following terms have the following meanings, unless otherwise indicated.

As used herein, the term “memory device” means a structure in which the electrical state can be altered and then retained in the altered state, in this way a bit of information can be stored.

A “memory material” is the material of the memory device that provides the function of storing an electrical state.

As used herein, a “copolymer” is a polymer composed of two or more dissimilar mer units in combination along its molecular chain.

As used herein, the term “block copolymer” means a copolymer in which the mer units of each block have a repeating subunit that are linked by covalent bonds. Block copolymers with two or three distinct blocks are called diblock copolymers and triblock copolymers, respectively. Block copolymers may have more than three distinct blocks.

A “mer” is a group of atoms that denotes a polymer chain repeat unit.

“Volatile memory” means memory in which stored information is lost when power to the memory cell is turned off.

“Non-volatile memory” means information that is stored is maintained after the power supply to the memory device is turned off.

As used herein, the term “resistive memory device” denotes a device whose effective electrical resistivity can be switched between two or more resistivities (ohms) upon an application of an energy pulse, such as a voltage or current pulse. Pulse time may range from approximately 5 nano-seconds to approximately 100 nano-seconds.

As used herein, a “phase change material” is a material that converts from a first phase to a second phase upon the application of energy.

The term “phase change material memory device” denotes a memory device including a memory cell composed of a phase change material.

As used herein, a “via” refers to a hole formed in a dielectric which is then filled with an electrically conductive material to provide a connection between interconnect lines and/or devices.

As used herein, a “metal” is an electrically conductive material, wherein in metal atoms are held together by the force of metallic bond, and the energy band structure of metal's conduction and valence bands overlap, and hence, there is no energy gap.

As used herein, a “barrier metal” is a material used to chemically isolate conductive, semiconducting and dielectric materials from one another, and provides electrical communication.

The term “electrode” denotes an electrically conductive material that applies external energy to an electrical device, such as a memory cell.

The term “sublithographic” means less than 0.06 micrometers.

As used herein, the terms “insulating” and “dielectric” denote a non-metallic material, wherein the room temperature conductivity of the material is less than about 10⁻¹⁰(Ω−m)⁻¹.

“Electrically conductive” and/or “electrically communicating” as used throughout the present disclosure means a material typically having a room temperature conductivity of greater than 10⁻⁸(Ω−m)⁻¹.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the invention, as it is oriented in the figures. Further, it will be understood that when an element as a layer, region or substrate is referred to as being “atop” or “over” or “overlying” or “below” or “underlying” another element, it can be directly on the other element or intervening elements may also be present. In contrast, when an element is referred to as being “directly on” or in “direct physical contact” with another element, there are no intervening elements present.

FIGS. 1 to 7 depict one embodiment of a process flow that utilizes a segregated copolymer as an etch mask to provide a via for a subsequently formed electrode, in accordance with the present invention. FIG. 1 depicts one embodiment of an interlevel dielectric layer 1 atop a substrate 2, such as a semiconducting wafer. In one embodiment, the present method may begin following front end of the line (FEOL) processing, in which an interlevel dielectric layer 1 has been formed having a plurality of openings 10 that are filled with at least one conductive material to provide interconnect structures, such as a metal stud 20 or bar 30. In one embodiment, the interlevel dielectric layer 1 may include a metal stud 20 that provides electrical conductivity to a first terminal (source/drain) of a select/access transistor (not shown) that is formed in the underlying substrate 2. In one embodiment, the interlevel dielectric layer 1 may also include at least one metal bar 30, wherein the metal bar 30 is a conducting line that may be used to provide electrical conductivity to the second terminal (source/drain) of a select/access transistor positioned in the underlying substrate 2. In one embodiment, the interlevel dielectric layer 1 may further include a lower conductive line 3. The lower conductive line 3 may be a word line, which may bias the gate of the select/access transistor that links the metal stud 20 with the metal bar 30.

The substrate 2 may include any number of active and/or passive devices (or regions) located within the substrate 2 or on a surface thereof. For clarity, the active and/or passive devices (or regions) are not shown in the drawings, but are nevertheless meant to be included in the substrate 2. For example, the substrate 2 may comprise any semiconductor material including, but not limited to: Si, Ge, SiGe, SiC, SiGeC, InAs, GaAs, InP and other III/V compound semiconductors. The substrate 2 may be undoped, or doped. In one example, when the substrate 2 is a Si-containing substrate, the doping of the Si-containing substrate may be light (having a dopant concentration of less than 1E17 atoms/cm³) or heavy (having a dopant concentration of about 1E17 atoms/cm³ or greater). The substrate 2 can have any crystallographic orientation such as (100), (110) or (111). In one embodiment, hybrid substrates having at least two planar surfaces of different crystallographic orientation are also contemplated.

In one embodiment, the interlevel dielectric layer 1 is formed atop the substrate 2 using deposition. More specifically, in one embodiment of the invention, the interlevel dielectric layer 1 is formed atop the substrate 2 by a deposition process including, but not limited to: chemical vapor deposition (CVD), plasma-assisted CVD, evaporation, spin-on coating, or chemical solution deposition. The interlevel dielectric layer 1 may include any suitable insulating material that is typically employed in interconnects to electrical devices. This includes inorganic dielectrics, organic dielectrics and combinations and multilayers thereof. Illustrative examples of suitable materials for the interlevel dielectric layer 1 include, but are not limited to: SiO₂, Boron Phospho Silicate Glass (BPSG) oxide, fluorinated SiO₂, SiN, organic thermoset or thermoplastic dielectrics such as polyimides, polyarylenes, benzocyclobutenes and the like, spun-on glasses including organosilicate glass (OSG), with or without porosity, such as hydrogen silsesquixoane, methyl silsesquixoane, tetraethylorthosilicate (TEOS) and the like, amorphous alloys of Si, O, C and H, or SiCOH, amorphous alloys of Si, O, F and H.

In one embodiment, the interlevel dielectric layer 1 comprises a low-k dielectric having a thickness ranging from about 10 nm to about 1000 nm. A low-k dielectric has a dielectric constant less than the dielectric constant of silicon oxide. In one embodiment, the dielectric constant of the interlevel dielectric layer 1 may be less than about 3.5. Low-k dielectrics may include organic dielectrics, such as low dielectric constant polymer dielectrics, or may include low dielectric constant carbon-doped oxides. One example of a low-k dielectric polymer dielectric is SiLK™. Specifically, SiLK™ is a class of polymer-based low-k dielectric materials comprising a b-staged polymer having a composition including about 95% carbon. An example of a low dielectric constant carbon doped oxide is SiCOH.

After forming the interlevel dielectric layer 1 on the surface of the substrate 2, openings 10 are formed into the interlevel dielectric layer 1 so as to expose portions of the underlying substrate 2, in which conductive structures, e.g., device interconnects, such as metal studs 20 and/or metal bars 30, are subsequently formed. In one embodiment, the openings 10 are provided with a circular cross section when viewed from the top view. The openings 10, hereafter referred to as lower vias, are formed utilizing lithography and etching. For example, the lithographic step may include applying a photoresist to the interlevel dielectric layer 1, exposing the photoresist to a pattern of radiation and developing the pattern into the exposed photoresist utilizing a resist developer. The etching step used in providing the lower vias 10 into interlevel dielectric layer 1 may include reactive ion etching (RIE), plasma etching, ion beam etching or laser ablation. Following etching, the photoresist is typically removed from the structure utilizing a resist stripping process, such as oxygen ashing.

In one embodiment, device interconnects, such as metal studs 20 and metal bars 30, are then formed within the lower vias 10 in the interlevel dielectric layer 1 using deposition processes. In one embodiment, a barrier metal liner 35 is positioned between the device interconnect via sidewalls, and the upper surface of the underlying substrate 2.

Still referring to FIG. 1, in one embodiment, the barrier metal liner 35 is deposited atop the horizontal and vertical surfaces of the lower via 10 within the interlevel dielectric layer 1. In one embodiment, the barrier metal liner 35 is a barrier metal. In one embodiment, the barrier metal liner 35 is a substantially conformal layer. The term “conformal layer” denotes a layer having a thickness that does not deviate from greater than or less than 20% of an average value for the thickness of the layer. In one embodiment, the barrier metal liner 35 may comprise TiN or TaN. In one embodiment, the barrier metal liner 35 may have a thickness ranging from about 2 nm to about 50 nm. In one embodiment, the barrier metal liner 35 may be deposited by sputter deposition. In another embodiment, the barrier metal liner 35 may be deposited by chemical vapor deposition. Chemical vapor deposition is a deposition process in which a deposited species is formed as a result of a chemical reaction between gaseous reactants at greater than room temperature, wherein solid product of the reaction is deposited on the surface on which a film, coating, or layer of the solid product is to be formed. Variations of CVD processes include, but are not limited to: Atmospheric Pressure CVD (APCVD), Low Pressure CVD (LPCVD), Plasma Enhanced CVD (EPCVD), Metal-Organic CVD (MOCVD) and combinations thereof. In one embodiment, the barrier metal liner 35 prevents the electromigration of a subsequently formed conductive material into the interlevel dielectric layer 1.

Following the formation of the barrier metal liner 35, a conductive material, such as Cu, Al, or W, is then formed utilizing a conventional deposition process, such as plating or sputtering, filling at least the lower vias 10. After filling the lower vias 10 with a conductive material, the structure is typically subjected to a planarization process, such as chemical-mechanical polishing or grinding, to provide a planar structure, as depicted in FIG. 1. Following planarization, the upper surface of conductive structures, e.g., metal studs 20 and/or metal bars 30, is substantially coplanar with the abutting upper surface of interlevel dielectric layer 1.

FIG. 2 is a side cross sectional view depicting recessing of the upper surface of the metal stud 20 below an upper surface 15a of the interlevel dielectric layer 1 to provide a recessed metal stud 20a, in accordance with one embodiment of the present invention. In one embodiment, a protective photomask 50 is formed over the metal bar 30 prior to etching of the metal studs 20. In one embodiment, the protective photomask 50 is formed by depositing a layer of photoresist atop the substantially planar surface of the interlevel dielectric layer 1, metal studs 20 and metal bar 30, wherein following deposition the photoresist is patterned to provide a photomask 50 that protects the metal bar 30.

Following photoresist patterning and development, the exposed portion of at least one conductive structure, e.g., metal studs 20, is recessed using an anisotropic etch process, e.g., reactive ion etching, selective to the interlevel dielectric layer 1 to provide a first cavity 21 in an upper portion of the lower via 10. In one embodiment when metal studs 20 are composed of tungsten (W), recessing the upper surface of the metal studs 20 includes reactive ion etch processing with a sulfur hexafluoride/oxygen inductively coupled plasma. In another embodiment, the reactive ion etch chemistry may be NF₃Cl₂. An inductively coupled plasma is a high density plasma generated by an axial magnetic field that induces an electric field with circulation in the plane of the wafer and produces a plasma in which its density is decoupled from the ion energy at the substrate/electrode. In one embodiment, the upper surface of the metal studs 20 are recessed from about 10 nm to about 250 nm from the upper surface 15a of the interlevel dielectric layer 1. In another embodiment, the upper surface of the metal studs 20 are recessed from about 30 nm to about 100 nm from the upper surface 15a of the interlevel dielectric layer 1. In a further embodiment, the upper surface of the metal studs 20 are recessed from about 20 nm to about 50 nm from the upper surface 15a of the interlevel dielectric layer 1. Following etch processing to recess the upper surface of the metal stud 20, the protective photomask 50 is removed using a chemical strip.

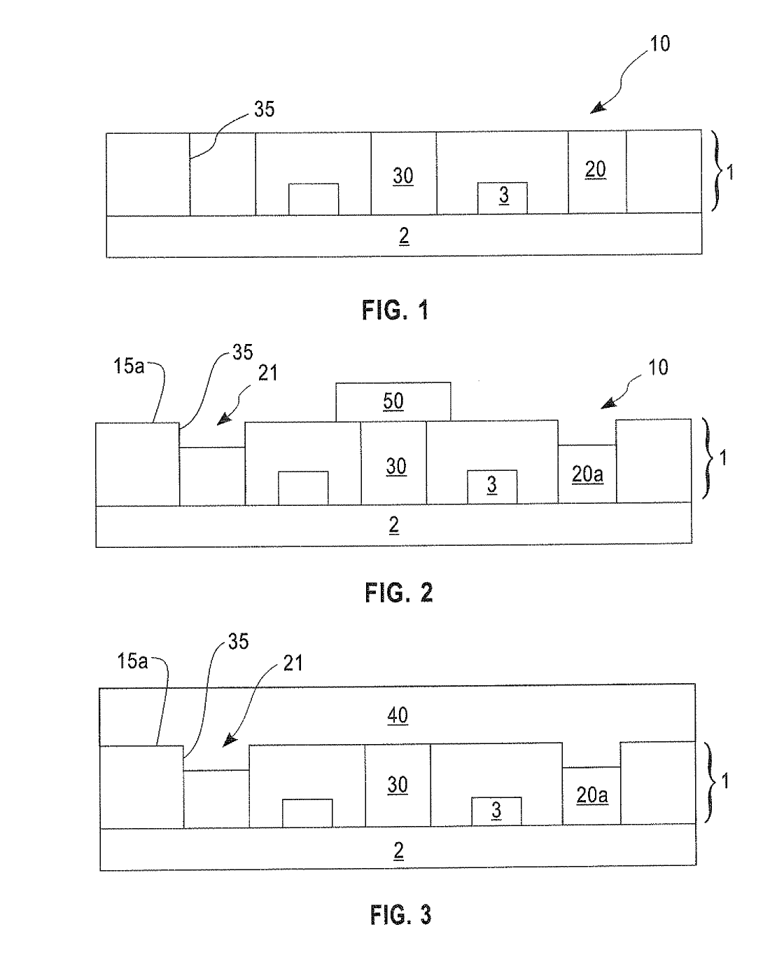

FIG. 3 depicts the formation of a memory material 40 atop the recessed metal stud 20a and the interlevel dielectric layer 1, in accordance with one embodiment of the present invention. In one embodiment, the memory material 40 is deposited atop the recessed metal stud 20a filling the first cavity 21 formed in the upper portion of the lower via 10. In one embodiment, the memory material 40 may be deposited by a physical deposition process, such as sputtering or plating. In another embodiment, the memory material 40 may be deposited by chemical vapor deposition. Although, the following description is directed to a phase change memory device including a phase change material, the present invention is applicable to other types of memory devices including non-volatile and volatile memory including resistive memory devices. Therefore, in addition to the phase change materials disclosed below, the memory material 40 may also include any material that can provide the memory cell of a memory device.

In one embodiment when the memory material 40 is composed of a phase change material, the phase change material may be switched from an amorphous phase to a crystalline phase. When in an amorphous state, the phase change material may exhibit a high resistivity, typically ranging from about 10² ohm-m to about 10⁴ ohm-m. When in a crystalline state, the phase change material may be more conductive in comparison to the amorphous state of the phase change material, wherein in one embodiment the crystal state of the phase change material may exhibit a resistivity typically ranging from about 10⁻⁵ ohm-m to about 10⁻² ohm-m. In one embodiment, the phase change material may be composed of chalcogenide alloys. The term “chalcogenide” is used herein to denote an alloy or compound material, which contains at least one element from group VI of the Periodic Table of Elements. Illustrative examples of chalcogenide alloys that can be employed herein include, but are not limited to, alloys of Te or Se with at least one of the elements of Ge, Sb, As, Si. In other embodiments, the phase change material is made of any suitable material including one or more of the elements Te, Ga, In, Se, and S. In one embodiment, the phase change material has a composition of Ge₂Sb₂Te₅ (GST). Although chalcogenides are a group of materials commonly utilized as phase change materials, some phase change materials, such as GeSb, do not utilize, chalcogenides. Thus, a variety of materials can be used for a phase change material as long as they can retain separate amorphous and crystalline states of distinct resistivity.

In one embodiment, a phase change material composed of GST is in an amorphous phase when at a temperature of about 25° C. As the temperature of the GST phase change material is increased to a temperature ranging from about 125° C. to about 150° C., the resistivity of the phase change material decreases representing the transition temperature for a phase change from an amorphous phase to Face Center Cubic (FCC) phase. Further increases in the temperature of the GST phase change material to greater than about 180° C. result in further decreases in resistivity, which result from a phase change from the Face Centered Cubic (FCC) phase to a Hexagonal (Hex) phase of the GST. When the temperature of the GST phase change material is increased above the melting temperature (approximately 620° C.), the GST phase change material melts and upon quenching returns to the amorphous solid phase. As used herein, the term “quenching” denotes solidification in a time period ranging from about 0.5 to about 50 nanoseconds.

Still referring to FIG. 3, in one embodiment when the memory material 40 is composed of a phase change material, a layer of a barrier metal (not shown) may be formed atop the recessed conductive stud 20a prior to the deposition of the memory material 40. In one embodiment, the barrier metal is TiN, TaN or a combination thereof.

In one embodiment, the layer of barrier metal may be blanket deposited by a physical deposition process, such as sputtering. In another embodiment, the layer of barrier metal may be deposited by chemical vapor deposition. In one embodiment, the layer of barrier metal may have a thickness ranging from about 20 nm to about 200 nm.

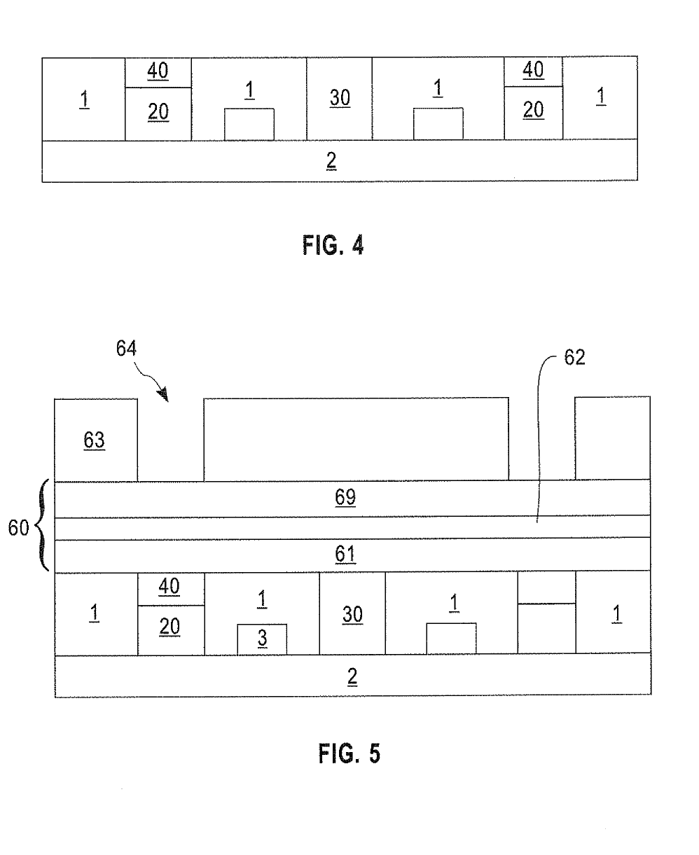

FIG. 4 depicts one embodiment of a planarization process applied to the memory material 40, in accordance with the present invention. Planarization is a material removal process that employs at least mechanical forces, such as frictional media, to produce a planar surface. In one embodiment, the planarization process includes Chemical Mechanical Planarization (CMP). Chemical mechanical planarization (CMP) is a material removal process using both chemical reactions and mechanical forces to remove material and planarize a surface. In one embodiment, the planarization process is continued to remove the portion of the memory material 40 that is formed atop the interlevel dielectric layer 1, wherein following the planarization step the upper surface of the memory material 40 within the first cavity 21 is coplanar with the upper surface of the interlevel dielectric layer 1.

In one embodiment, a layer of a barrier metal (not shown) may be formed at an interface of the memory material 40 and a subsequently formed upper electrode. In one embodiment, the layer of barrier metal may be composed of TiN, TaN or a combination thereof. In one embodiment, the layer of barrier metal is blanket deposited by a physical deposition process, such as sputtering. In another embodiment, the layer of barrier metal may be deposited by chemical vapor deposition. In one embodiment, the layer of barrier metal may have a thickness ranging from about 20 nm to about 200 nm.

FIG. 5 depicts one embodiment of forming at least one insulating layer 60 atop an upper surface of the memory material 40 and the interlevel dielectric layer 1, and forming a patterned block mast atop the at least one insulating layer to provide an opening 63 exposing a portion of the at least one insulating layer overlying the memory material 40, in accordance with the present invention. In one embodiment, the at least one insulating layer 60 is provided by a layered stack. In one embodiment, the layered stack includes a first insulating layer 61 formed atop the upper surface of the interlevel dielectric layer 1 and the upper surface of the memory material 40, and a second insulating layer 62 formed atop the first insulating layer 61, and in a preferred embodiment a third insulating layer 69 formed atop the first insulating layer 62. In one embodiment, the at least one insulating layer 60 may be formed by a deposition process including, e.g., chemical vapor deposition (CVD), plasma-assisted CVD, evaporation, spin-on coating, or chemical solution deposition. In one embodiment, forming the at least one insulating layer includes chemical vapor deposition of the first insulating layer 61 being composed of a nitride, such as SiN, and chemical vapor deposition of the second insulating layer 62 being composed of an oxide, such as SiCOH. In one embodiment when the first insulating layer 61 is composed of a nitride, the thickness of the first insulating layer 61 may range from about 10 nm to about 100 nm. In one embodiment when the second insulating layer 62 is composed of an oxide, the thickness of the second insulating layer 62 may range from about 10 nm to about 50 nm. In one embodiment when the third insulating layer 69 is composed of a nitride, the thickness of the third insulator 69 may range from about 10 nm to about 500 nm.

In one embodiment, the at least one insulating layer 60 will be subsequently patterned. In one embodiment, the patterning of the at least one insulating layer 60 may be provided by a block mask, which may be composed of photoresist. In one embodiment, forming the block mask 63 may include depositing a layer of photoresist atop the third insulating layer 69, exposing the layer of photoresist to a pattern of radiation, and then developing the pattern into the layer of photoresist utilizing a resist developer. In one embodiment, the regions 64 exposed by the block mask 63 are then processed, while the regions underlying the block mask 63 are protected.

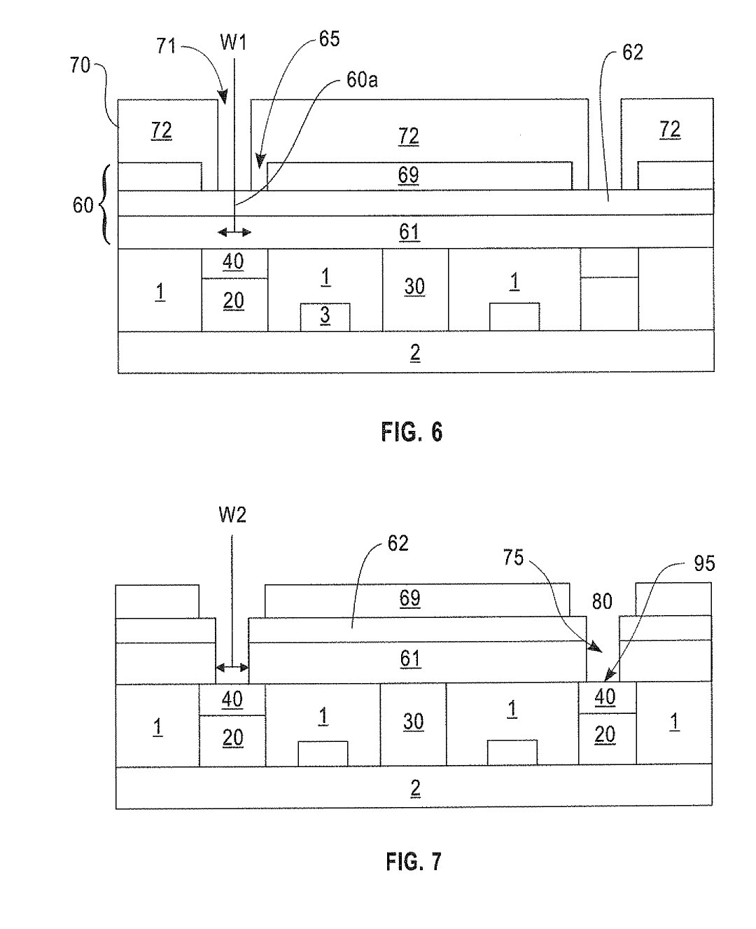

FIG. 6 depicts one embodiment of forming the second cavity 65 through a portion of a thickness of the at least one insulating layer 60, wherein a remaining portion 60a of the at least one insulating layer 60 overlies the memory material 40. In one embodiment the thickness of the remaining portion 60a is about the thickness of the second insulating layer 62, In one embodiment, the second cavity 65 is provided by a timed etch step. In one embodiment when the third insulating layer 69 is composed of a nitride, the etch process may include an anisotropic etch. An anisotropic etch process is a material removal process in which the etch rate in the direction normal to the surface to be etched is greater than in the direction parallel to the surface to be etched. In one embodiment, the anisotropic etch process is provided by Reactive Ion Etching (RIE). Reactive ion etching (RIE) is a form of plasma etching in which the surface to be etched is placed on the RF powered electrode, wherein the surface to be etched takes on a potential that accelerates the etching species extracted from a plasma toward the surface to be etched, in which a chemical etching reaction is taking place in the direction normal to the surface. In one embodiment when the second insulating layer 62 is composed of an oxide, the reactive ion etch process includes an etch gas chemistry of CHF₃ mixed with O₂ or CF₄ mixed with O₂. Other etch gas chemistries may include SiF₄, NF₃, CHF₃ and C₂F₆.

In one embodiment, in which the third insulating layer 69 has a thickness ranging from about 10 nm to about 500 nm, the second cavity 65 has a depth ranging from about 15 nm to about 250 nm. In one embodiment the thickness of the remaining portion of the at least one insulating layer 60 atop the memory material 40 is equal to the thickness of the remaining portion of the second insulating layer 62 plus the thickness of the first insulating layer 61. In one embodiment, the combined thickness of the remaining portion of the second insulating layer plus the first insulating layer 61 may range from about 15 nm to about 150 nm.

In one embodiment, the etch process for providing the second cavity 65 is a selective etch process. In one embodiment, the etch process is a selective etch process that removes the third insulating layer 69 selective to the second insulating layer 62. In one embodiment in which the second insulating layer 62 is composed of an oxide and the third insulating layer 69 is composed of nitride the selective etch process that provides the second cavity 65 removes nitrides selective to oxides includes an etch gas chemistry of. CH₃F mixed with O₂. In one embodiment, the thickness of the remaining portion of the at least one insulating layer 60 atop the memory material 40 is equal to the thickness of the second insulating layer 62.

In one embodiment, forming the copolymer mask 70 includes forming a layer of a block copolymer within at least the second cavity 65, wherein the block copolymer may be segregated and developed to provide openings of a sublithographic width. In one embodiment, forming the copolymer block mask 70 includes depositing a layer of a block copolymer in at least the second cavity 65, segregating the block copolymer into first units and second units, exposing the first units and second units, with a radiation, and removing at least one the first units or second units with a selective developer, wherein the selective developer dissolves the composition of one of the first or second units.

In one embodiment, the block copolymer may be composed of a self-assembled block copolymer that is annealed to form an ordered pattern containing repeating structural units, e.g., segregating into first and second structural units. There are many different types of block copolymers that can be used for practicing the present invention, as long as block copolymer contains two or more different polymeric block components that are not immiscible with one another, such two or more different polymeric block components are capable of separating into two or more different phases on a nanometer scale and thereby form patterns of isolated nano-sized structural units under suitable conditions. In one embodiment of the present invention, the block copolymer includes a first polymeric block component and second polymeric block component, e.g., first units and second units, which are immiscible with each other. Hereafter, first polymeric block component (first units) and second polymeric block component (second units) of the layer of block copolymer are interchangeably referred to as block component A and a block component B.

In one embodiment, the block copolymer may contain any numbers of the polymeric block components A and B arranged in any manner. For example, the block copolymer can have either a linear or a branched structure. In one embodiment, the block copolymer is a linear diblock copolymer having the formula of A-B. Further, the block copolymer can have any one of the following formula:

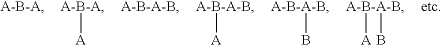

Specific examples of suitable block copolymers that can be used for forming the structural units of the present invention may include, but are not limited to: polystyrene-block-polymethylmethacrylate (PS-b-PMMA), polystyrene-block-polyisoprene (PS-b-PI), polystyrene-block-polybutadiene (PS-b-PBD), polystyrene-block-polyvinylpyridine (PS-b-PVP), polystyrene-block-polyethyleneoxide (PS-b-PEO), polystyrene-block-polyethylene (PS-b-PE), polystyrene-b-polyorganosilicate (PS-b-POS), polystyrene-block-polyferrocenyldimethylsilane (PS-b-PFS), polyethyleneoxide-block-polyisoprene (PEO-b-PI), polyethyleneoxide-block-polybutadiene (PEO-b-PBD), polyethyleneoxide-block-polymethylmethacrylate (PEO-b-PMMA), polyethyleneoxide-block-polyethylethylene (PEO-b-PEE), polybutadiene-block-polyvinylpyridine (PBD-b-PVP), and polyisoprene-block-polymethylmethacrylate (PI-b-PMMA).

In one embodiment when the block copolymer is poly(styrene)-poly(L-lactide) (PS-PLLA) chiral block copolymer, the first units are polystyrene, and the second units are poly(L-lactide). In another embodiment when the block copolymer is poly(4-vinylpyridine)-poly(L-lactide) (P4VP-PLLA) chiral block copolymer, the first units are poly(4-vinylpyridine), and the second units are block poly(L-lactide). In a further embodiment when the block copolymer is poly(acrylonitrile)-poly(caprolactone) (PVHF-PCL) block copolymer, the first units are poly(acrylonitrile), and the second units are poly(caprolactone). In yet another embodiment when the block copolymer is poly(acrylonitrile)-poly(caprolactone) (PVHF-PCL) block copolymer, the first units are poly(acrylonitrile) and the second units are poly(caprolactone). In an even further embodiment when the block copolymer is poly(styrene)-poly(methyl-methacry-late), the first units are poly(styrene), and the second units are poly(methyl-methacry-late).

The specific structural units formed by the block copolymer are determined by the molecular weight ratio between the first and second polymeric block components A and B. In one embodiment, the molecular weight ratio between the first and second polymeric block components A and B can be adjusted in the block copolymer of the present invention in order to form structural units of a desired geometry. For example, when the ratio of the molecular weight of the first polymeric block component A, i.e., a first unit composed of polystyrene, over the molecular weight of the second polymeric block component B, i.e., second unit composed of methylmethacrylate (PMMA), is greater than about 80:20, the block copolymer will form an ordered array of spheres composed of the second polymeric block component B. i.e., the second unit being composed of methylmetacrylate (PMMA), in a matrix composed of the first polymeric block component A, i.e., the first unit being composed of polystyrene (PS).

In another example, when the ratio of the molecular weight of the first polymeric block component A over the molecular weight of the second polymeric block component B is less than about 80:20 but greater than about 60:40, the block copolymer will form an ordered array of cylinders composed of the second polymeric block component B in a matrix composed of the first polymeric block component A.

In a further example, when the ratio of the molecular weight of the first polymeric block component A over the molecular weight of the second polymeric block component B is less than about 60:40 but is greater than about 40:60, the block copolymer will form alternating lamellae composed of the first and second polymeric block components A and B.

In yet another example, the ratio of the molecular weight of the first polymeric block component A over the molecular weight of the second polymeric block component B ranges from about 80:20 to about 60:40, so that the block copolymer will form an ordered array of lines composed of the second polymeric block component B in a matrix composed of the first polymeric block component A.

Typically, mutual repulsion between different polymeric block components in a block copolymer is characterized by the term χN, where χ is the Flory-Huggins interaction parameter and N is the degree of polymerization. The higher χN, the higher the repulsion between the different blocks in the block copolymer, and the more likely the phase separation therebetween. When χN>10 (which is hereinafter referred to as the strong segregation limit), there is a strong tendency for the phase separation to occur between different blocks in the block copolymer.

For a PS-b-PMMA diblock copolymer, χ can be calculated as approximately 0.028+3.9/T, where T is the absolute temperature. Therefore, χ is approximately 0.0362 at 473K(≈200° C.). When the molecular weight (Mₙ) of the PS-b-PMMA diblock copolymer is approximately 64 Kg/mol, with a molecular weight ratio (PS:PMMA) of approximately 66:34, the degree of polymerization N is about 622.9, so χN is approximately 22.5 at 200° C.

In this manner, by adjusting one or more parameters such as the composition, the total molecular weight, and the annealing temperature, the mutual compulsion between the different polymeric block components in the block copolymer of the present invention can be readily controlled to effectuate desired phase separation between the different block components. The phase separation in turn leads to formation of self-assembled periodic patterns containing ordered arrays of repeating structural units (i.e., spheres, lines, cylinders, or lamellae).

In order to form the self-assembled periodic patterns, the block copolymer is first dissolved in a suitable solvent system to form a block copolymer solution, which is then applied onto a surface to form the layer of block copolymer, followed by annealing of the layer of block copolymer, thereby effectuating phase separation between different polymeric block components, i.e., first and second units contained in the block copolymer.

The solvent system used for dissolving the block copolymer and forming the block copolymer solution may comprise any suitable solvent, including, but not limited to: toluene, propylene glycol monomethyl ether acetate (PGMEA), propylene glycol monomethyl ether (PGME), and acetone. In one embodiment, the block copolymer solution contains the block copolymer at a concentration ranging from about 0.1% to about 2% by total weight of the solution. In another embodiment, the block copolymer solution contains the block copolymer at a concentration ranging from about 0.5 wt % to about 1.5 wt %. In a further embodiment, the block copolymer solution is composed of about 0.5 wt % to about 1.5 wt % PS-b-PMMA dissolved in toluene or PGMEA.

The block copolymer solution can be applied to the second cavity 65 and the upper surface of the at least one insulator 60 by any suitable technique, including, but not limited to: spin casting, coating, spraying, ink coating, dip coating, and combinations thereof.

After application of the layer of block copolymer to the second cavity 65 and the upper surface of the at least one insulating layer 60, the structure may be annealed to effectuate at least micro-phase segregation of the different block components contained by the block copolymer, thereby forming the periodic patterns with repeating structural units, i.e., first units and second units. The annealing of the layer of block copolymer can be achieved by various methods including, but not limited to: thermal annealing (either in a vacuum or in an inert atmosphere containing nitrogen or argon), ultra-violet annealing, laser annealing, solvent vapor-assisted annealing (either at or above room temperature), supercritical fluid-assisted annealing and combinations thereof.

In one embodiment of the present invention, a first annealing step is carried out to segregate the layer of block copolymer at an annealing temperature that is above the glass transition temperature (T_{g}) of the block copolymer, but below the decomposition or degradation temperature (T_{d}) of the block copolymer. In one embodiment, the thermal annealing step is carried out with an annealing temperature ranging from about 200° C. to about 300° C. In one embodiment, the thermal annealing may last from less than about 1 hour to about 100 hours, and more typically from about 1 hour to about 15 hours. In another embodiment of the present invention, the block copolymer layer is annealed by ultra-violet (UV) treatment.

Following the anneal process, one of the components of the block copolymer can be removed utilizing a solvent that is selective to that component relative to the other component of the block copolymer. The type of solvent may vary and can be, for example, selected from the following list: polar and aprotic solvents. After removing the removable component of the block copolymer, the remaining “unremovable” component 72 serves as an etch mask 70. In one embodiment, since self-assembled polymer technology is used in the inventive process, the width, W₁, of each single repeating unit, i.e, first units and second units, is less than 50 nm. Therefore, by removing one of the first or second units to provide the etch mask 70, the openings 71 within the etch mask 70 have a width W₁ on the order of 50 nm or less. In one embodiment, the width W₁ of the openings 71 within the etch mask 70 range from about 10 nm to about 40 nm.

FIG. 7 depicts etching the exposed surface of the remaining portion 60a of the at least one insulating layer 60 to provide an upper via 75 to the memory material 40 and forming a conductive material 80 within the upper via 75 in electrical contact with the memory material 40. In one embodiment, etching is performed utilizing a dry etching process such as reactive ion etching, ion beam etching, plasma etching or laser ablation. In one embodiment, the etch process for providing the upper via 75 is an anisotropic etch process, such as reactive ion etch. In one embodiment, the etch process for providing the upper via 75 includes an etch chemistry for removing the exposed remaining portion of the second insulating layer 62 (where present) and the exposed first insulating layer 61 selective to the underlying conductive structure, e.g., metal stud 20a. In one embodiment, the etch process to provide the upper via 75 includes at first etch step for removing the exposed remaining portion of the second insulating layer 62 selective to the first insulating layer 61, and a second etch step for removing the exposed first insulating layer 61 selective to the underlying conductive structure, i.e., metal stud 20a. Following the first etch step, the unconsumed block copolymer mask 70 may be removed utilizing a resist stripping process, such as oxygen ashing.

In one embodiment, because the first units and second units of the segregated block copolymer each have a width on the order of less than approximately 50 nm, by removing one of the first or second units to provide the etch mask 70, the opening within the etch mask 70 has a width W₁ on the order of 50 nm or less. Therefore, the upper via 75 that is formed by the etch processes using the etch mask 70 provided by the segregated block copolymer may have a width W₂ on the order of 50 nm or less.

Still referring to FIG. 7, in a following step, an upper electrode 80 may be formed within the upper via 75. The upper electrode 80 may be formed by physical vapor deposition, such as plating or sputtering. In one embodiment, the upper electrode 80 is composed of tungsten, copper, aluminum, silver, gold and multilayers and alloys thereof. In one embodiment, the upper electrode 80 may further include a silicide surface (not show). In one embodiment, the surface area of the direct physical contact 95 of the memory material 40 and the upper electrode 80 may range from about 100 nm² to about 10000 nm².

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of manufacturing a memory device comprising:
providing an interlevel dielectric layer including a first via containing a memory material;
forming at least one insulating layer on an upper surface of the memory material and an upper surface of the interlevel dielectric layer;
forming a cavity through a portion of a thickness of the at least one insulating layer, wherein a remaining portion of the at least one insulating layer overlies the memory material;
forming a copolymer mask in at least the cavity, the copolymer mask comprising at least one opening that provides an exposed surface of the remaining portion of the at least one insulating layer that overlies the memory material;
etching the exposed surface of the remaining portion of the at least one insulating layer to provide a second via to the memory material; and
forming a conductive material within the second via in electrical contact with the memory material.

2. The method of claim 1, wherein each of the at least one opening in the copolymer mask comprises a sublithographic width.

3. The method of claim 1 further comprising a liner of a barrier metal between a sidewall of the first via and the memory material.

4. The method of claim 1, wherein forming the at least one insulating layer comprises chemical vapor deposition of a first insulating layer composed of a nitride atop the interlevel dielectric layer, and chemical vapor deposition of a second insulating layer composed of an oxide atop the first insulating layer and chemical vapor deposition of a third insulating layer composed of a nitride atop the second insulating layer.

5. The method of claim 1, wherein the etching of the exposed surface of the remaining portion of the at least one insulating layer to provide the second via to the memory material comprises an anisotropic etch process.

6. The method of claim 1, wherein the depth of the cavity ranges from about 15 nm to about 250 nm from an upper surface of the at least one insulating layer.

7. The method of claim 1, wherein the width of the cavity ranges from about 25 nm to about 200 nm.

8. The method of claim 1, wherein the forming of the copolymer mask comprises: forming a copolymer layer on at least the remaining portion of the at least one insulating layer;
segregating the copolymer into first units and second units; and
removing the first units or second units with a selective developer.

9. The method of claim 8, wherein the copolymer layer comprises polystyrene-block-polymethylmethacrylate (PS-b-PMMA), polystyrene-block-polyisoprene (PS-b-PI), polystyrene-block-polybutadiene (PS-b-PBD), polystyrene-block-polyvinylpyridine (PS-b-PVP), polystyrene-block-polyethyleneoxide (PS-b-PEO), polystyrene-block-polyethylene (PS-b-PE), polystyrene-b-polyorganosilicate (PS-b-POS), polystyrene-block-polyferrocenyldimethylsilane (PS-b-PFS), polyethyleneoxide-block-polyisoprene (PEO-b-PI), polyethyleneoxide-block-polybutadiene (PEO-b-PBD), polyethyleneoxide-block-polymethylmethacrylate (PEO-b-PMMA), polyethyleneoxide-block-polyethylethylene (PEO-b-PEE), polybutadiene-block-polyvinylpyridine (PBD-b-PVP), or polyisoprene-block-polymethylmethacrylate (PI-b-PMMA).

10. The method of claim 8, wherein the copolymer layer is a poly(styrene)-poly(L-lactide) (PS-PLLA) chiral block copolymer, the first units are polystyrene, and the second units are poly(L-lactide).

11. The method of claim 8, wherein the copolymer layer is a poly(4-vinylpyridine)-poly(L-lactide) (P4VP-PLLA) chiral block copolymer, the first units are poly(4-vinylpyridine), and the second units are block poly(L-lactide).

12. The method of claim 8, wherein the copolymer layer is poly(acrylonitrile)-poly(caprolactone) (PVHF-PCL) block copolymer, the first units are poly(acrylonitrile), and the second units are poly(caprolactone).

13. The method of claim 8, wherein the copolymer layer is poly(acrylonitrile)-poly(caprolactone) (PVHF-PCL) block copolymer, the first units are poly(acrylonitrile) and the second units are poly(caprolactone).

14. The method of claim 8, wherein the copolymer layer is poly(styrene)-poly(methyl-methacry-late), the first are poly(styrene), and the second units are poly(methyl-methacrylate).

15. The method of claim 8, wherein the copolymer layer comprises 70% polystyrene (PS) and 30% poly(methyl-methacry-late).

16. The method of claim 8, wherein converting the copolymer layer to the first units and the second units comprises segregating at a temperature ranging from about 200° C. to about 300° C. for a time period ranging from about 1 hour to about 300 hours.
